(19) United States
(12) Patent Application Publication
(10) Pub. No.: US 2008/0042192 A1
(43) Pub. Date: Feb. 21, 2008

(54) SEMICONDUCTOR MEMORY DEVICE INCLUDING CHARGE TRAP LAYER WITH STACKED NITRIDE LAYERS

(75) Inventors: Kwangmin Park, Seoul (KR); Kihyun Hwang, Gyeonggi-do (KR); Jae-Young Ahn, Gyeonggi-do (KR); Seung-Hwan Lee, Gyeonggi-do (KR); Ju-Wan Lim, Seoul (KR); Sung-Hae Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/782,858

(22) Filed: Jul. 25, 2007

(30) Foreign Application Priority Data
Aug. 18, 2006 (KR) 10-2006-0078108
Oct. 26, 2006 (KR) 10-2006-0104683

(51) Int. Cl. H01L 29/792

(52) U.S. Cl. 257/324; 257/E29.309

(57) ABSTRACT

A semiconductor memory device includes a semiconductor substrate, a tunnel insulating layer, charge trap layer, and a blocking layer. The tunnel insulating layer is on the semiconductor substrate. The charge trap layer is on the tunnel insulating layer and includes at least one pair of a first nitride layer with a higher trap density of holes than electrons and a second nitride layer with a higher trap density of electrons than holes. The blocking layer is on the charge trap layer opposite to the tunnel insulating layer. The first nitride layer may include silicon rich nitride, which may have a ratio of silicon to nitride of greater than 1 and less than or equal to 2. The second nitride layer may include aluminum nitride which may have a hexagonal crystalline structure.

### CROSS-REFERENCE TO RELATED PATENT APPLICATION

This application claims priority under 35 U.S.C. §119 from Korean Patent Application No. 10-2006-0078108, filed on Aug. 18, 2006, and Korean Patent Application No. 10-2006-0104683, filed on Oct. 26, 2006, in the Korean Intellectual Property Office, the disclosures of which are incorporated herein in their entirety by reference.

### FIELD OF THE INVENTION

The present invention relates to semiconductor memory devices and, more particularly, to charge trap type semiconductor memory devices.

### BACKGROUND OF THE INVENTION

Generally, semiconductor memory devices that can maintain data in the absence of a power supply are referred to as nonvolatile memory devices. Because of their nonvolatile data storage capability, nonvolatile memory devices are widely incorporated in consumer electronics such as mobile telecommunication terminals and removable memory cards. Some nonvolatile memory devices store and erase charges in a single charge trap layer of a memory cell.

FIG. 1 is a sectional view illustrating a conventional semiconductor memory device including a charge trap layer.

Referring to FIG. 1, the semiconductor memory device includes a tunnel insulating layer 12, a charge trap layer 14, a blocking layer 16 and a gate electrode 18 that are sequentially stacked on a substrate 10, e.g., a silicon substrate. Charges are trapped in the charge trap layer 14 and retained therein by a difference of energy band values of the tunnel insulating layer 12, the blocking layer 16 and the charge trap layer 14, which forms a single level cell (SLC). The SLC can store a single bit of information in the charge trap layer 14.

The maximum threshold voltage V_{TH}, also referred to as a memory window, that can be used to program and erase the nonvolatile memory device is constrained due to inherent characteristics of the material used to form the charge trap layer 14. For a single level cell, the threshold voltage V_{TH} corresponds to a voltage that is sufficient to cause programming or erasure of the single charge trap layer 14.

Higher capacity semiconductor memory devices have been suggested that may be formed using a multi level cell (MLC) that is configured to store plural bits of information in a single cell. Such MLCs may be difficult to operate because the programming and erasing threshold voltages may be relatively large. However, the programming and erasing speed for storing and reading out information from a MLC may be higher than a single level cell because the capacity of the MLC type semiconductor memory device is increased. Accordingly, although a SLC type device can have a threshold voltage that is more easily obtained than for a MLC type device, the speed of the MLC type device can be greater than that of a SLC type device.

### SUMMARY OF THE INVENTION

In accordance with some embodiments, a semiconductor memory device includes a semiconductor substrate, a tunnel insulating layer, a charge trap layer, and a blocking layer. The tunnel insulating layer is on the semiconductor substrate. The charge trap layer is on the tunnel insulating layer and includes at least one pair of a first nitride layer with a higher trap density of holes than electrons and a second nitride layer with a higher trap density of electrons than holes. The blocking layer is on the charge trap layer opposite to the tunnel insulating layer.

In accordance with some further embodiments, the first nitride layer may include silicon rich nitride (SRN). The SRN of the first nitride layer may have a ratio of silicon (Si) to nitride (N) of greater than 1 and less than or equal to 2. The second nitride layer may include aluminum nitride (AlN), which may have a hexagonal crystalline structure.

The first nitride layer and the tunnel insulating layer may be configured to have a valence energy band relative difference of from 2 eV to 3 eV. The second nitride layer and the tunnel insulating layer may be configured to have a valence energy band relative difference of from 1 eV to 1.5 eV.

The first nitride layer and the blocking layer may be configured to have a valence energy band relative difference of from 2.5 eV to 3.5 eV. The second nitride layer and the blocking layer may be configured to have a valence energy band relative difference of from 1 eV to 1.5 eV.

The charge trap layer may include a plurality of stacked pairs of the first nitride layer on the second nitride layer or vice versa.

### BRIEF DESCRIPTION OF THE DRAWINGS

Other features of the present invention will be more readily understood from the following detailed description of the invention when read in conjunction with the accompanying drawings, in which:

FIG. 1 is a sectional view illustrating a conventional semiconductor memory device including a charge trap layer;

FIG. 2A is a band diagram illustrating relative energy band values when a silicon nitride (Si₃N₄) layer with a higher trap density of holes than electrons is used as the charge trap layer in accordance with some embodiments of the present invention;

FIG. 2B is a graph comparing drain current ID that may result from gate voltages V_{G} applied to a semiconductor memory device having a silicon rich nitride (SRN) charge trap layer according to some embodiments of the present invention, and to a semiconductor memory device having a low pressure (LP) SiN charge trap layer;

FIG. 3A is a band diagram illustrating relative energy band values when aluminum nitride (AlN) with a higher trap density of electrons than holes is used as a charge trap layer in accordance with some embodiments of the present invention;

FIG. 3B is a graph plotting programming and erasing operations to the AlN charge trap layer of FIG. 3A with a voltage V and a capacitance density fF/μm² in accordance with some embodiments of the present invention;

FIGS. 4A through 4C are sectional views conceptually illustrating a semiconductor memory device with a first charge trap layer formed by sequentially stacking a first nitride layer and a second nitride layer, a second charge trap layer formed by sequentially stacking the second nitride layer and the first nitride layer, and a third charge trap layer formed by a plurality of first charge trap layers, respectively;

FIG. 5A is a graph plotting threshold voltages over time for programming a semiconductor memory device having a conventional LP SiN charge trap layer, and for programming a semiconductor memory device having a hybrid charge trap layer (SRN and AlN composite layer) according to some embodiments of the present invention;

FIG. 5B is a graph plotting threshold voltages over time for erasing a semiconductor memory device having a conventional LP SiN charge trap layer, and for erasing a semiconductor memory device having a hybrid charge trap layer (SRN and AlN composite layer) according to some embodiments of the present invention; and

FIG. 6 is a graph illustrating a comparison of the threshold voltages that may be provided by a semiconductor memory device having a conventional LP SiN charge trap layer and by a semiconductor memory device having a hybrid charge trap layer (SRN and AlN composite layer) according to some embodiments of the present invention.

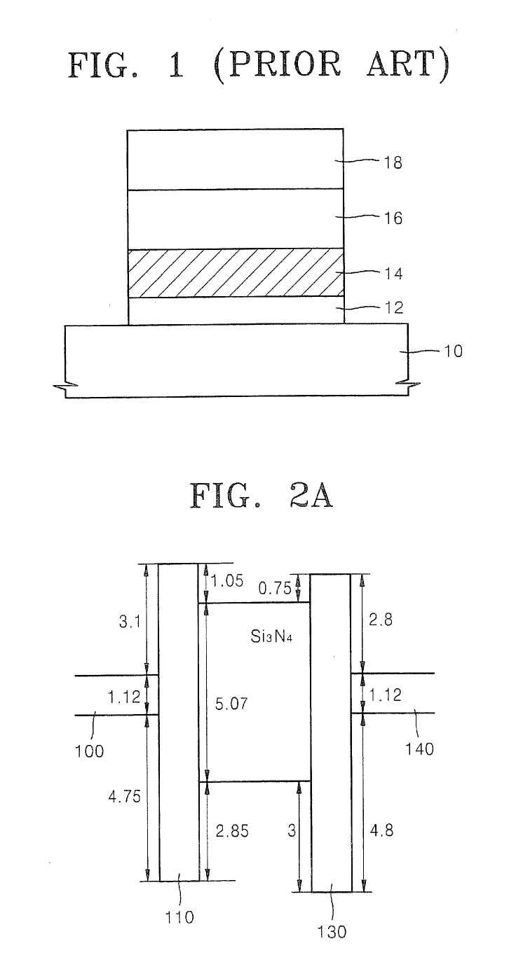

### DETAILED DESCRIPTION OF THE INVENTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a film, layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of films, layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an etched/implanted region illustrated as a rectangle will, typically, have rounded or curved features and/or a gradient of implant concentration at its edges rather than a discrete change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

According to some embodiments of the present invention, a semiconductor memory device includes a charge trap layer formed from a nitride layer with a higher trap density of holes than electrons and a nitride layer with a high trap density of electrons than holes. The nitrite layer with the higher trap density of the holes than electrons, in the charge trap layer, may be formed from silicon rich nitride (SRN) and/or from aluminium nitride (AlN). The trap densities of the holes and electrons are determined by a relative difference of energy band values.

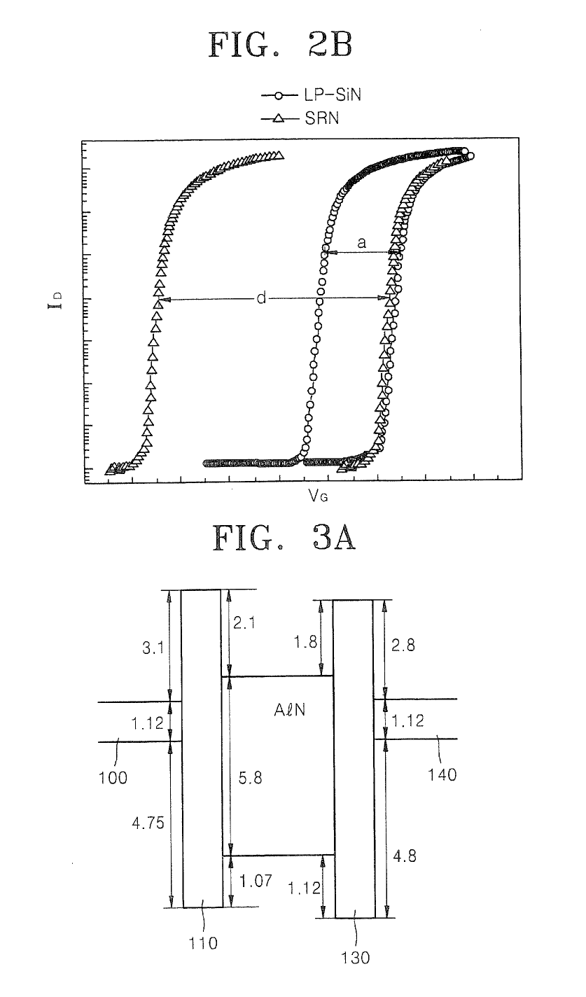

FIG. 2A is a band diagram illustrating relative energy band values when a silicon nitride (Si₃N₄) layer with a higher trap density of holes than electrons is used as the charge trap layer. Here, Si₃N₄ has less silicon content than SRN according to some embodiments of the present invention, but is used as the charge trap layer for purposes of explanation of the nitride layer with the higher trap density of the holes than electrons according to some embodiments of the present invention.

Referring to FIG. 2A, the semiconductor memory device with Si₃N₄ as the charge trap layer includes a substrate 100 on which a tunnel insulating layer 110, the Si₃N₄ layer configured as the charge trap layer, a blocking layer 130 and a gate electrode 140 are sequentially stacked. As used herein, “semiconductor substrate” refers to a semiconductor layer that may include, but is not limited to, silicon on insulator and/or an epitaxial layer. In this embodiment, the substrate 100 includes silicon, the tunnel insulating layer 110 includes silicon oxide (SiO₂), the blocking layer 130 includes aluminum oxide (Al₂O₃), and the gate electrode 140 includes polysilicon.

A relative difference Δ Ev between valence energy bands of the silicon oxide layer 110 and the Si₃N₄ layer can be 2.85 eV, and a relative difference Δ Ec of conduction energy bands can be 1.05 eV. As shown by the relative valence energy bands, the Si₃N₄ layer provides more favorable characteristics of retaining substantially more trapped holes rather than retaining electrons. Also, a relative difference Δ Ev between the valence energy bands of the Si₃N₄ layer and the Al₂O₃ layer 130 can be 3.0 eV, and a relative difference Δ Ec between the conduction energy bands of the Si₃N₄ layer and Al₂O₃ layer 130 can be 0.75 eV. Accordingly, the Si₃N₄ charge trap layer provides favorable characteristics of trapping substantially more holes than electrons.

According to some embodiments of the present invention, a relative difference Δ Ev between the valence energy bands of the Si₃N₄ layer (the first nitride layer) with a higher trap density of holes than electrons compared to the tunnel insulating layer 110 can be from 2 eV to 3 eV, and a relative difference Δ Ev between the valence energy bands of the Si₃N₄ and the blocking layer 130 can be from 2.5 eV to 3.5 eV.

FIG. 2B is a graph comparing drain current I_{D} that may result from gate voltages V_{G} applied to a semiconductor memory device having SRN (denoted by Δ) charge trap layer according to some embodiments of the present invention, to a semiconductor memory device having a LP SiN (denoted by ∘) charge trap layer.

As shown in FIG. 2B, forming a charge trap layer from SRN results in a different relationship between the gate voltage V_{G} and the drain current I_{D} compared to when the charge trap layer is formed from LP SiN. These differences between the gate voltage V_{G} to drain current I_{D} relationships illustrate some effects of the content of silicon (Si) and nitride (N) in a charge trap layer on the characteristics of the device. In the exemplary embodiment, programming may be performed with a gate voltage V_{G} of 17V for 100μ sec, and erasing may be performed with a gate voltage V_{G} of −19V for 10 msec.

With continued reference to FIG. 2B, a voltage difference (hereinafter designated by Δ V_{TH}) between the gate voltage V_{G} for programming and erasing the semiconductor memory device having the LP SiN charge trap layer is shown as “a”. In this case, the LP SiN is configured to have a ratio of atomic weights of silicon to nitride of 1. In sharp contrast, the voltage difference Δ V_{TH} for programming and erasing the semiconductor memory device having the SRN charge trap layer, in accordance with some embodiments of the present invention, is shown as “d”.

Accordingly, as illustrated, the voltage Δ V_{TH} of the semiconductor memory device having a charge trapping layer including SRN may be significantly greater than that of the semiconductor memory device having a charge trapping layer including LP SiN. Moreover, as illustrated, the threshold voltage of the SRN charge trapping layer is further moved toward the negative voltage (e.g., a greater negative erasing voltage) than the threshold voltage of the LP-SiN charge trapping layer. The increased voltage difference Δ V_{TH} caused by the SRN charge trapping layer can be particularly useful when the SRN is used in a multi level cell (MLC) that stores plural bits of information in a single cell.

According to some embodiments of the present invention, the SRN charge trap layer with the higher trap density of holes than electrons may have a ratio of the atomic weights of Si to N greater than 1 (SiN) and smaller than 2 (Si₂N) so as to provide a suitable ratio of atomic weights. However, the Si and N ratio is not limited to less than 2, because other ratios of the atomic weights may be suitable for a charge trapping layer in some semiconductor memory devices. Therefore, if the nitride layer with the higher trap density of holes than electrons is not a silicon nitride layer, the ratio of the atomic weights may be determined in another way. Accordingly, although the charge trap layer is described as including SRN (nitride layer) with a higher trap density of holes than electrons, any material which may provide similar characteristics to those described above with regard to the energy band diagram and that controls the threshold voltage difference Δ V_{TH} relative to the applied voltage may be used without limitation. The charge trap layer may therefore include, but is not limited to, SRN.

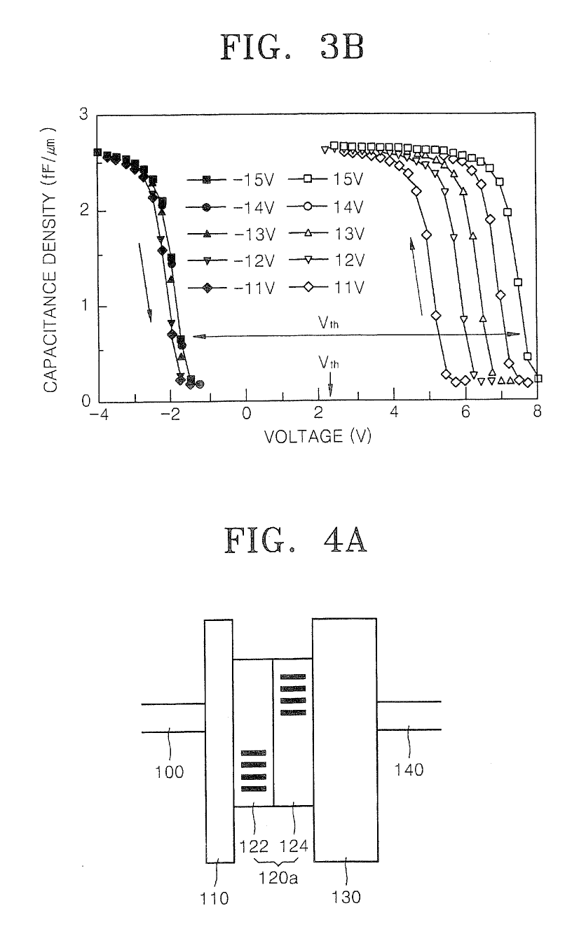

FIG. 3A is a band diagram illustrating relative energy band values when aluminum nitride (AlN) with a higher trap density of electrons than holes is used as a charge trap layer in accordance with some embodiments of the present invention.

Referring to FIG. 3A, a semiconductor memory device includes a substrate 100 on which a tunnel insulating layer 110, a charge trap layer that includes AlN, a blocking layer 130, and a gate electrode 140 that are sequentially stacked. In this embodiment, the substrate 100 includes silicon, the tunnel insulating layer 110 includes silicon oxide (SiO₂), the blocking layer 130 includes aluminum oxide (Al₂O₃), and the gate electrode 140 includes polysilicon. As illustrated, a difference Δ Ev of valence energy bands of the silicon oxide layer 110 and the AlN layer 120 can be 1.07 eV, and a difference Δ Ec of conduction energy bands can be 2.1 eV. The AlN charge trap layer may therefore retain substantially more trapped electrons rather than holes. Also, a difference Δ Ev of the valence energy bands of the aluminum layer 130 and the AlN layer can be 1.12 eV, and a difference Δ Ec of the conduction energy bands can be 1.8 eV. In other words, the AlN charge trap layer is more favorable for trapping substantially more electrons than holes.

The AlN layer (the second nitride layer) with a higher trap density of electrons than holes applicable to some embodiments of the present invention has a relative difference Δ Ev between the valence energy bands thereof and the tunnel insulating layer 110 of from 1 ev to 1.5 eV, and a relative difference Ev between the valence energy bands thereof and the blocking layer 130 of from 1 ev to 1.5 eV.

FIG. 3B is a graph plotting programming and erasing operations of the AlN charge trap layer of FIG. 3A with a voltage V and a capacitance density fF/μm² in accordance with some embodiments of the present invention. In this embodiment, programming is performed by regulating the gate voltage V_{G} to 11V(⋄), 12V(∇), 13V(Δ), 14V(∘) and 15V(□), respectively. Erasing is performed by regulating the gate voltage V_{G} to −11V(♦), −12V(▾), −13V(▴), −14V() and −15(▪), respectively.

Referring to FIG. 3B, the semiconductor memory device using the AlN charge trap layer has an increasing threshold voltage V_{TH} as the program voltage is increased. As illustrated, the threshold voltage V_{TH} applied to the AlN charge trap layer is moved toward a greater positive voltage (e.g., increased positive voltage) relative to the voltage applied to the AlN charge trap layer. The increased voltage difference Δ V_{TH} provided by the AlN charge trap layer can be particularly useful when the AlN charge trap layer is used in a multi level cell (MLC) that stores plural bits of information in a single cell. The AlN charge trap layer can have a hexagonal structure.

In FIGS. 3A and 3B, although the charge trap layer is described as including AlN (nitride layer) with a higher trap density of electrons than holes, any material that may provide similar characteristics to the above-described energy band diagram and controlling the voltage Δ V_{TH} relative to the applied voltage may be used without limitation. The charge trap layer may therefore include, but is not limited to, AlN.

In accordance with some other embodiments, a semiconductor memory device that includes a charge trap layer (hybrid trap layer) formed by stacking a nitride layer (a first nitride layer) configured to provide a higher trap density of holes than electrons and a nitride layer (a second nitride layer) configured to provide a higher trap density of electrons than holes will be described.

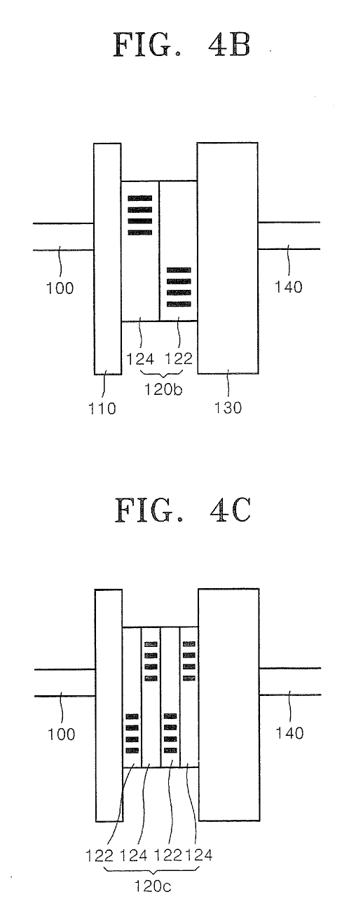

FIGS. 4A through 4C are sectional views conceptually illustrating a semiconductor memory devices according to some embodiments of the present invention. More specifically, FIG. 4A illustrates a first charge trap layer 120a on the tunnel insulating layer 110. The first charge trap layer 120a is formed by sequentially stacking a first nitride layer 122 and a second nitride layer 124. FIG. 4B illustrates a second charge trap layer 120b on the tunnel insulating layer 110. The second charge trap layer 120b is formed by sequentially stacking the second nitride layer 124 and the first nitride layer 122. FIG. 4C illustrates a third charge trap layer 120c formed by stacking a plurality of the first charge trap layers 120a of FIG. 4A on the tunnel insulating layer 110. Alternatively, a plurality of the second charge trap layers 120b of FIG. 4B may be stacked on the tunnel insulating layer 110 to form a third charge trap layer 120c. Accordingly, the charge trap layers 120a, 120b and 120c may be configured to have various different structures that provide desired characteristics for the semiconductor memory device. The trapped electrons and holes are denoted by a plurality of dark rectangles.

Referring to FIGS. 4A through 4C, the tunnel insulating layer 110 is formed by growing a SiO₂ layer to a thickness of 15˜50 Å by thermal oxidation of the substrate 100, e.g., a silicon substrate. A hybrid charge trap layer is then grown to a thickness of 10˜20 Å on the tunnel insulating layer 110. The first nitride layer 122 may be formed on the tunnel insulating layer 110 by growing the SRN layer to have a thickness of 10˜200 Å by Low Pressure Chemical Vapor Deposition (LPCVD) and/or Atomic Layer Deposition (ALD). The second nitride layer 124 may then be formed on the first nitride layer 122 by growing the AlN layer to have a thickness of 10˜200 Å by LPCVD and/or ALD. The blocking layer 130 may then be formed on the second nitride layer 124 from a least one high-k dielectric such as SiO₂, Al₂O₃, Hf₂O, Si₃N₄ which is grown to a thickness of 10˜200 Å. In this embodiment, the first nitride layer 122 and the second nitride layer 124 may be continuously formed within one chamber without breaking vacuum in the chamber.

As illustrated in FIG. 4A, when an AlN layer as the second nitride layer 124 is interposed between the first nitride layer 122, which is formed of a SiₓN_{y} layer, such as an SRN layer, and the blocking layer 130, which is formed of an Al₂O₃ layer, the semiconductor memory device may have the following characteristics. When Al₂O₃ is deposited directly on the SiₓN_{y} layer, an unwanted layer, for example, a SiON layer, may be formed on the SiₓN_{y} layer. The unwanted layer reduces the electric field applied to the tunnel insulating layer 110. However, when the AlN layer is deposited on the SiₓN_{y} layer, the formation of the unwanted layer may be substantially reduced or prevented. Accordingly, using AlN in the second nitride layer 124 may allow the electric field applied to the tunnel insulating layer 110 to be maintained at a desired level in a stabilize the threshold voltage for programming and/or erasing the memory device.

Referring to FIG. 4B, when an AlN layer as the second nitride layer 124 is interposed between the tunnel insulating layer 110 and the first nitride layer 122, which is formed of an SiₓN_{y} layer as, for example, an SRN layer, the semiconductor memory device may have the following characteristics. The first nitride layer 122, which is a charge trapping material layer, has a high hole-trapping density, and thus acts as a low-energy trap. The trapped charges in the low-energy trap can more easily drop out of the substrate 100 through the lower tunnel insulating layer 110, which deteriorates the charge retention properties of the memory device. However, when the second nitride layer 124 formed of AlN is between the tunnel insulating layer 110 and the first nitride layer 122 formed of SiₓN_{y}, dropping of charges out of the substrate 110 through the tunnel insulating layer 110 may be substantially reduced or prevented.

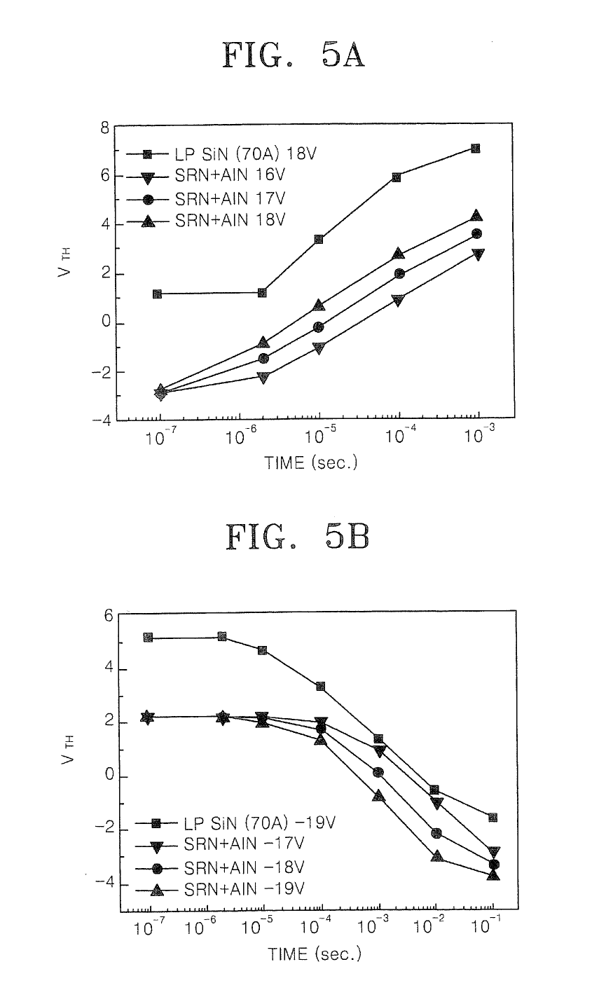

FIG. 5A is a graph plotting the threshold voltages over time for programming the semiconductor memory device having a conventional LP SiN charge trap layer, and for programming a semiconductor memory device having a hybrid charge trap layer (SRN and AlN composite layer) according to some embodiments of the present invention. A LP-SiN charge trap layer having a thickness of 70 Å may be used in the conventional semiconductor memory device, and is supplied with a voltage of 18V (▪). The hybrid trap layer in the semiconductor memory device according to some embodiments of the present invention includes a SRN layer having a thickness of 70 Å and an AlN layer having a thickness of 120 Å, resulting in a combined thickness of 190 Å. The supplied voltage is regulated to levels of 16V(▾), 17V() and 18V(▴). Respective semiconductor memory devices are formed to have the same structure and the same material excluding the charge trap layer, i.e., the tunnel insulating layer of SiO₂ to a thickness of 35 Å, the blocking layer of Al₂O₃ to a thickness of 150 Å, and the TaN gate electrode.

Referring to FIG. 5A, the threshold voltage V_{TH} is 1.9V when 17V is supplied to the semiconductor memory device, which is configured in accordance with some embodiments, for 100 μs. Similar variation in the threshold voltages over time is observed for the semiconductor memory device configured in accordance with some embodiments of the present invention and the conventional semiconductor memory device. The charge trap layer of a semiconductor memory device configured according to some embodiments of the present invention may be thicker than the conventional charge trap layer by about 120 Å. As the thickness of the charge trap layer of a semiconductor memory device according to some embodiments of the present invention is reduced, such as to be the same thickness as that of the charge trap layer of the conventional semiconductor memory device, the threshold voltage may have a greater change in magnitude over time. Accordingly, use of the hybrid charge trap layer may increase the programming speed of a semiconductor memory device configured in accordance with some embodiments of the present invention compared to the conventional semiconductor memory device.

FIG. 5B is a graph plotting threshold voltages over time for erasing a semiconductor memory device having a conventional LP SiN charge trap layer, and for erasing a semiconductor memory device having a hybrid charge trap layer (SRN and AlN composite layer) according to some embodiments of the present invention.

A SiN charge trap layer having a thickness of 70 Å may be used in the conventional semiconductor memory device (▪) and supplied with a voltage of −19V. The hybrid trap layer in the semiconductor memory device according to some embodiments of the present invention includes the SRN layer having a thickness of 70 Å and the AlN layer having a thickness of 120Å, resulting in a combined thickness of 190Å. The supplied voltage is regulated to levels of −17V(▾), −18V() and −19V(▴) to measure the effects on threshold voltage over time for the conventional semiconductor memory device and various other semiconductor memory device configured in accordance with some embodiments of the present invention. Respective semiconductor memory devices are formed to have the same structure and the same material excluding the charge trap layer, i.e., the tunnel insulating layer of SiO₂ to a thickness of 35 Å, the blocking layer of Al₂O₃ to a thickness of 150 Å, and the TaN gate electrode of 150 Å.

Referring to FIG. 5B, when a gate voltage V_{G} of −17V is supplied for 10 ms to the semiconductor memory device configured according to some embodiments of the present invention, the threshold voltage V_{TH} is −3.1V. Also, the rate of variation of the threshold voltages of the semiconductor memory device configured according to some embodiments of the present invention and the conventional semiconductor memory device are similar to each other in that their threshold voltages V_{TH} display similar pattern of variation over time. However, the charge trap layer of a semiconductor memory device configured in accordance with some embodiments of the present invention can be thicker than the conventional charge trap layer by about 120 Å. As the thickness of the charge trap layer of a semiconductor memory device according to some embodiments of the present invention is reduced, such as to be the same thickness as that of the charge trap layer of the conventional semiconductor memory device, the threshold voltage may have a greater change in magnitude over time. Accordingly, use of the hybrid charge trap layer may increase the programming speed of a semiconductor memory device configured in accordance with some embodiments of the present invention compared to the conventional semiconductor memory device.

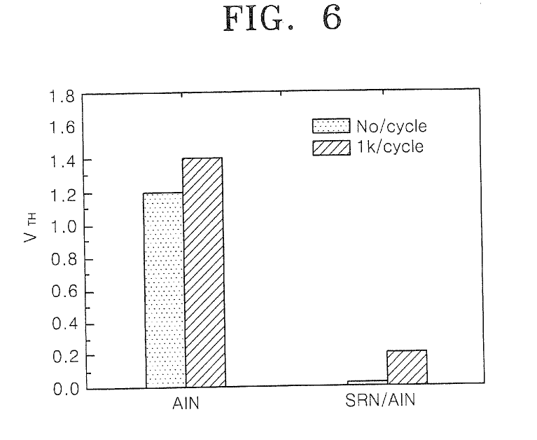

FIG. 6 is a graph illustrating a comparison of the threshold voltages that may be provided by a semiconductor memory device having a conventional LP SiN charge trap layer and by a semiconductor memory device having a hybrid charge trap layer (SRN and AlN composite layer) according to some embodiments of the present invention. The semiconductor memory devices may be baked at a temperature of 250° C. for 2 hours, and measured at 85° C. In this graph of FIG. 6, the bar filled with dots represents the semiconductor memory device which is not subjected to repeated programming and erasing, and the oblique-lined bar represents the semiconductor memory device subjected to 1,000 cycles of programming and erasing.

Referring to FIG. 6, the conventional semiconductor memory device provides a threshold voltage V_{TH} variation of about 1.2V in the case of not being subjected to repeated programming and erasing, and about 1.4V of threshold voltage V_{TH} variation in the case of being subjected to 1,000 cycles of programming and erasing. In sharp contrast, the semiconductor memory device with a hybrid charge trap layer (SRN and AlN composite layer), configured according to some embodiments of the present invention, displays a threshold voltage V_{TH} variation of about 0.02V in the case of not being subjected to repeated programming and erasing, and about 0.2V of threshold voltage V_{TH} variation in the case of being subjected to 1,000 cycles of programming and erasing. Consequently, the semiconductor memory device configured according to some embodiments of the present invention may achieve only a small threshold voltage V_{TH} variation over time, which may improve stability of the semiconductor memory device as it is subjected to high cumulative programming and erasing cycles over its lifetime.

Thus, in accordance with some embodiments, a semiconductor memory device includes a charge trap layer that is formed from at least one pair of a first nitride layer with a higher trap density of holes than electrons and a second nitride layer with a higher trap density of electrons than holes, which may reduce variation in its threshold voltage over time, and may increase the speed at which the device can be programmed and erased.

In accordance with some further embodiments, a semiconductor memory device configured according to some embodiments of the present invention may provide a greater difference between a threshold voltage used for programming and a threshold voltage used for erasing the device, which may provide particular advantages when used in a multi level cell (MLC) capable of storing plural bits of information within a single cell.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor memory device comprising:
a semiconductor substrate;
a tunnel insulating layer on the semiconductor substrate;
a charge trap layer on the tunnel insulating layer, the charge trap layer including at least one pair of a first nitride layer configured to have a higher trap density of holes than electrons and a second nitride layer configured to have a higher trap density of electrons than holes; and
a blocking layer on the charge trap layer opposite to the tunnel insulating layer.

2. The semiconductor memory device of claim 1, wherein:
the first nitride layer and the tunnel insulating layer are configured to have a relative valence energy band difference from 2 eV to 3 eV; and
the second nitride layer and the tunnel insulating layer are configured to have a relative valence energy band difference from 1 eV to 1.5 eV.

3. The semiconductor memory device of claim 1, wherein:
the first nitride layer and the blocking layer are configured to have a relative valence energy band difference from 2.5 eV to 3.5 eV; and
a second nitride layer and the blocking layer are configured to have a relative valence energy band difference from 1 eV to 1.5 eV.

4. The semiconductor memory device of claim 1, wherein the first nitride layer is directly on the tunnel insulating layer and the second nitride layer is directly on the first nitride layer.

5. The semiconductor memory device of claim 1, wherein the second nitride layer is directly on the tunnel insulating layer and the first nitride layer is directly on the second nitride layer.

6. The semiconductor memory device of claim 1, wherein the charge trap layer includes a plurality of stacked pairs of the first nitride layer on the second nitride layer.

7. The semiconductor memory device of claim 1, wherein the charge trap layer includes a plurality of stacked pairs of the second nitride layer on the first nitride layer.

8. The semiconductor memory device of claim 1, wherein the charge trap layer with the at least one pair of first and second nitride layers is configured so that a threshold voltage of the first nitride layer is more negative relative to a threshold voltage of a charge trap layer having a single SiN layer.

9. The semiconductor memory device of claim 1, wherein the charge trap layer with the at least one pair of first and second nitride layers is configured so that a threshold voltage of the second nitride layer is more positive relative to a threshold voltage of a charge trap layer having a single SiN layer.

10. The semiconductor memory device of claim 1, wherein a variation rate of the threshold voltages over time has a similar pattern even though a width of the charge trap layer is greater than a width of the SiN single layer by a multiple of from 2.5 to 3.5.

11. The semiconductor memory device of claim 1, wherein the first nitride layer comprises silicon rich nitride (SRN).

12. The semiconductor memory device of claim 11, wherein a ratio of silicon (Si) to nitride (N) in the SRN of the first nitride layer is greater than 1 and less than or equal to 2.

13. The semiconductor memory device of claim 11, formed by depositing the SRN of the first nitride layer by Chemical Vapor Deposition (CVD) and/or Atomic Layer Deposition (ALD).

14. The semiconductor memory device of claim 1, wherein the second nitride layer comprises aluminum nitride (AlN).

15. The semiconductor memory device of claim 14, wherein the AlN of the second nitride layer has a hexagonal crystalline structure.

16. The semiconductor memory device of claim 14, formed by depositing the AlN of the second nitride layer by Chemical Vapor Deposition (CVD) and/or Atomic Layer Deposition (ALD).

17. A semiconductor memory device comprising:
a semiconductor substrate;
a tunnel insulating layer on the semiconductor substrate;
a charge trap layer on the tunnel insulating layer, the charge trap layer including at least one pair of a silicon rich nitride (SRN) layer, having a ratio of silicon (Si) to nitride (N) greater than 1 and less than or equal to 2, and an aluminum nitride (AlN) layer; and
a blocking layer on the charge trap layer opposite to the tunnel insulating layer.

18. The semiconductor memory device of claim 17, wherein the charge trap layer includes a plurality of stacked pairs of the SRN layer on the AlN layer.

19. The semiconductor memory device of claim 18, wherein the AlN layer has a hexagonal crystalline structure.
